(19) United States
(12) Patent Application Publication
(10) Pub. No.: US 2026/0358675 A1
(43) Pub. Date: Nov. 12, 2026

(54) AN OPTICAL PRINTED CIRCUIT BOARD

(71) Applicant: Telefonaktiebolaget LM Ericsson (publ), Stockholm (SE)

(72) Inventors: Alessandra BIGONGIARI, Pisa (IT); Paolo DEBENEDETTI, Genova (IT); Fabio CAVALIERE, Pisa (IT); Sergio MOSTI, Genova (IT)

(73) Assignee: Telefonaktiebolaget LM Ericsson (publ), Stockholm (SE)

(21) Appl. No.: 19/515,080

(22) PCT Filed: Sep. 1, 2023
(86) PCT No.: PCT/EP2023/074090

§ 371 Date: Feb. 27, 2026

(51) Int. Cl. G02F 1/313

(52) U.S. Cl. CPC G02F 1/3137

(57) ABSTRACT

An optical printed circuit board, PCB, (200, 410, 500, 700, 810A, 810B, 910, 1010, 1500, 1600) comprising a plurality of optical waveguides (202, 502, 602A, 602B, 602C, 902, 1002, 1102, 1606); an optical switch (204, 504, 604, 804, 904, 1004, 1104, 1607); and an optical coupler (206, 606B, 606C, 906, 908, 1006A, 1006B, 1008, 1605) adapted to optically couple the plurality of optical waveguides and the optical switch to an optical device (320, 430, 920, 1020A, 1020B, 1120A, 1120B, 1503, 1603). The optical switch is configured to direct light into one or more optical waveguides of the plurality of optical waveguides. The optical switch is controllable to select the one or more optical waveguides into which light is directed.

### TECHNICAL FIELD

The disclosure relates to an optical printed circuit board; a system comprising an optical printed circuit board; a method of fabricating an optical printed circuit board; and a method of fabricating a system comprising an optical printed circuit board.

### BACKGROUND

The introduction of co-packaged optics (CPO) and near-packaged optics (NPO) technology to replace pluggable optical modules for high-capacity Application-Specific Integrated Circuits (ASICs) has reduced hardware power consumption in data centres. The conversion of optical signals to electrical signals via pluggable optical modules (transceivers) uses electrical signals at high rates which reduces the energy efficiency and implies tighter design constraints. CPO and NPO technologies both integrate the optical module on a printed circuit board (PCB) substrate such that a separate pluggable optical module is not required. This allows data that is received by optical fibre to reach the ASIC more efficiently by moving only a short distance on a very low-loss substrate. CPO refers to the coupling of the optical module and the ASIC in one package (e.g., on one PCB), while NPO refers to the coupling of the optical module with a PCB substrate, which can in turn be coupled to the ASIC. Thus, CPO and NPO technologies eliminate or reduce the need for electrical signal regeneration on the PCB, thereby reducing power consumption.

FIG. 1 illustrates a CPO device 100 that may be used in a data centre according to existing technology. Optical fibres 102 transmit optical signals to optical devices 104 mounted on a PCB 106. The optical devices 104 convert the optical signals into electrical signals that are transmitted to an ASIC 108 at the centre of the PCB 106.

A plurality of such CPO devices 100 may be interconnected using optical fibres (e.g., ribbons) connected via chiplets on top or at the sides of the ASIC 108 and passed over the PCB 106.

New research indicates that, in future, the optical fibres for interconnecting CPO devices may be replaced by polymer-based lanes deployed directly within the PCB. Furthermore, CPO and NPO technology could be used in future telecommunication applications to provide similar power consumption reduction benefits.

### SUMMARY

As described above, existing CPO and NPO technology integrates optical and electrical wiring onto the same PCB. According to existing technology, both the optical part of the PCB and the electrical part of the PCB are fixed once the PCB has been made. Therefore, a problem with existing technology is that a change in either the electrical or optical wiring of a CPO or NPO device requires a full redesign of the entire PCB, which is costly for the hardware supplier. Indeed, the optical part of the PCB is likely to have high associated manufacturing costs because precise alignment of optical couplers to the ASIC is required.

A further problem with existing co-packaged and near-packaged technology is that the interconnection of CPO/NPO devices requires optical fibres to be connected to the PCB (e.g., to an ASIC). Thus, the interconnection of CPO/NPO devices is highly space consuming and restrictive.

It is thus an object of the disclosure to obviate or eliminate at least some of the above-described disadvantages associated with existing technology.

The optical wiring on the PCB of a CPO/NPO device has greater design flexibility than the electrical wiring. The electrical wiring is bound by tight constraints to avoid crosstalk and electromagnetic interference (EMI) and to maintain signal integrity. For example, the electrical signals over PCB wires emit electromagnetic fields and therefore lose power, an effect that is stronger the higher the frequency. With higher bit rates, digital regeneration circuitry is typically included to recover the signal, and re-timing is required. This process consumes power and increases heating. In contrast, the optical wiring typically does not suffer from EMI problems and there is no requirement to regenerate.

The present disclosure proposes to exploit the greater design flexibility of the optical wiring on the PCB by decoupling the optical part of the PCB from the electrical part of the PCB.

According to a first aspect of the disclosure, there is provided an optical PCB comprising a plurality of optical waveguides; an optical switch; and an optical coupler adapted to optically couple the plurality of optical waveguides and the optical switch to an optical device. The optical switch is configured to direct light into one or more optical waveguides of the plurality of optical waveguides. The optical switch is controllable to select the one or more optical waveguides into which light is directed.

According to a second aspect of the disclosure, there is provided a system comprising an optical PCB according to the first aspect in which the optical switch is adapted to be electrically coupled to an electrical PCB layer. The system further comprises one or both of: the electrical PCB layer electrically coupled to the optical switch; and the optical device optically coupled to the optical coupler of the optical PCB.

According to a third aspect of the disclosure, there is provided a method of fabricating an optical PCB. The optical PCB comprises: a plurality of optical waveguides; an optical switch; and an optical coupler adapted to optically couple the plurality of optical waveguides and the optical switch to an optical device. The optical switch is configured to direct light into one or more optical waveguides of the plurality of optical waveguides. The optical switch is controllable to select the one or more optical waveguides into which light is directed.

According to a fourth aspect of the disclosure, there is provided a method of fabricating a system. The method comprises: obtaining an optical PCB fabricated according to the method of the third aspect; and one or both of: depositing an electrical PCB layer onto the optical PCB; and depositing the optical device onto the optical PCB.

Thus, in the manner described above, an optical PCB that is configurable for different applications, e.g., CPO/NPO applications, is provided, as well as a system comprising the optical PCB. A plurality of different optical paths through the optical PCB can be configured by controlling the optical switch(es) in the optical PCB to select the one or more optical waveguides into which light is directed. As such, the same optical PCB can be provided for different custom applications. For example, the optical PCB may be configurable to interconnect optical devices, e.g., CPO and/or NPO devices. An electrical PCB layer may be designed to configure/reconfigure and control the optical switch(es) of the optical PCB. The electrical PCB layer may provide electrical power to the optical device(s) that are optically coupled to the optical PCB and/or enable the optical device(s) to exchange electrical signals with each other and with other devices.

A method of fabricating an optical PCB and a method of fabricating a system comprising the optical PCB are also provided. These methods provide an universal optical PCB that can be configured/reconfigured for different applications.

The present disclosure thereby reduces the hardware manufacturing complexity and reduces the non-recurring engineering costs by removing the need to re-design the optical part of the PCB for each application or each time there is a change to the optical or electrical wiring.

Furthermore, the flexibility of the interconnection between optical devices (e.g., CPO and NPO devices) may be improved relative to existing techniques. For example, the disclosed optical PCB allows optical coupling to be hidden in the PCB instead of using optical fibres running over the components (which has an associated risk of errors, detachment, reduced airflow, lack of physical access to the device, etc.). This optical coupling may thereby reduce power consumption, heating, and EMI.

Other aspects and embodiments of the techniques described herein will be understood by those skilled in the art based on the description below and the accompanying drawings.

### BRIEF DESCRIPTION OF THE DRAWINGS

For a better understanding of the techniques, and to show how they may be put into effect, reference will now be made, by way of example, to the accompanying drawings, in which:

FIG. 1 is a schematic illustrating a CPO device according to known techniques;

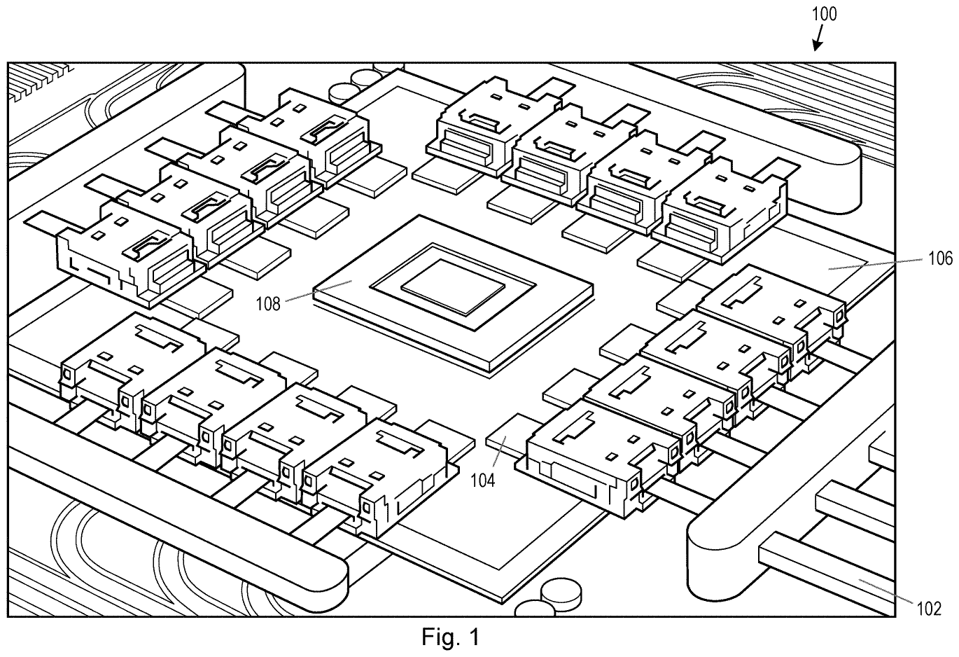

FIG. 2 is a block diagram illustrating an optical PCB in accordance with some embodiments;

FIG. 3 is a block diagram illustrating a system in accordance with some embodiments;

FIG. 4 is a schematic illustrating a system in accordance with some embodiments;

FIG. 5 is a schematic illustrating an optical PCB according to some embodiments;

FIG. 6 illustrates a possible function of an optical switch according to some embodiments;

FIG. 7 illustrates the interconnection of optical PCBs in accordance with some embodiments;

FIG. 8A illustrates a system in accordance with some embodiments;

FIG. 8B illustrates a system in accordance with some embodiments;

FIG. 9 illustrates a system in accordance with some embodiments;

FIG. 10 illustrates a system in accordance with some embodiments;

FIG. 11 illustrates a system in accordance with some embodiments;

FIG. 12 illustrates a method of fabricating an optical PCB in accordance with some embodiments;

FIG. 13 illustrates a method of fabricating an optical PCB in accordance with some embodiments;

FIG. 14 illustrates a method of fabricating a system in accordance with some embodiments;

FIGS. 15A, 15B and 15C illustrate a method of fabricating an optical PCB and a system in accordance with some embodiments; and

FIGS. 16A, 16B and 16C illustrate a method of fabricating an optical PCB and a system in accordance with some embodiments.

### DETAILED DESCRIPTION

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

Some of the embodiments contemplated herein will now be described more fully with reference to the accompanying drawings. Other embodiments, however, are contained within the scope of the subject-matter disclosed herein, the disclosed subject-matter should not be construed as limited to only the embodiments set forth herein; rather, these embodiments are provided by way of example to convey the scope of the subject-matter to those skilled in the art.

In some instances, detailed descriptions of well-known methods, nodes, interfaces, circuits, and devices are omitted so as not obscure the description with unnecessary detail.

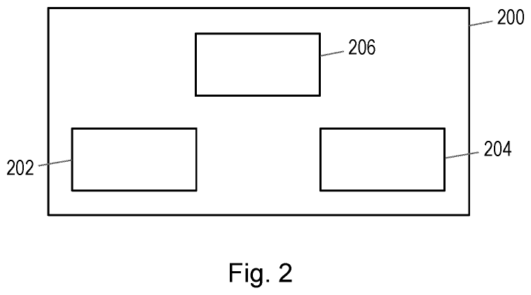

FIG. 2 is a block diagram illustrating an optical PCB 200 in accordance with some embodiments. The optical PCB 200 comprises a plurality of optical waveguides 202; an optical switch 204; and an optical coupler 206. The plurality of optical waveguides 202 and the optical switch 204 may be referred to herein as a waveguide mesh or an optical waveguide mesh. The optical PCB 200 may be comprised of, for example, glass (e.g., engineered glass) or a polymer material.

The optical coupler 206 is adapted to optically couple the plurality of optical waveguides and the optical switch to an optical device. The optical device may be, for example, an electro-optical device, such as a co-packaged optical (CPO) device or a near-packaged optical (NPO) device. The optical device may be, for example, a transceiver, a further optical coupler, or a filter. The optical PCB 200 may comprise a trench for housing the optical device, and the optical coupler 206 may be adapted to optically couple the optical PCB 200 to the optical device by directing light towards the trench.

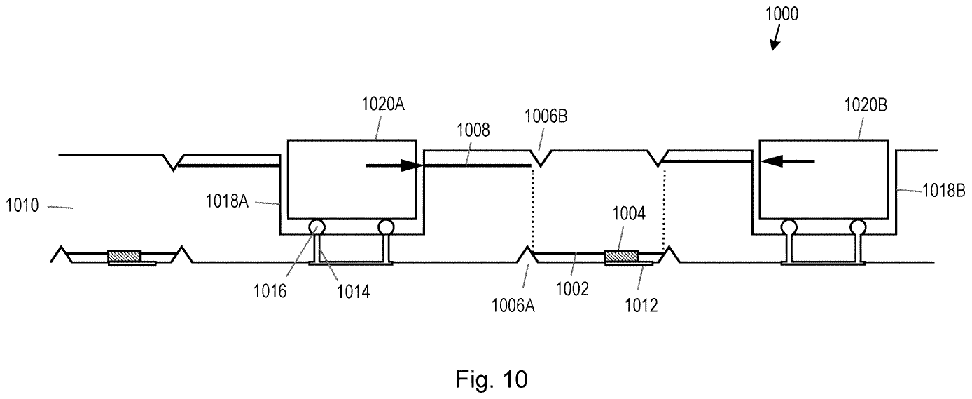

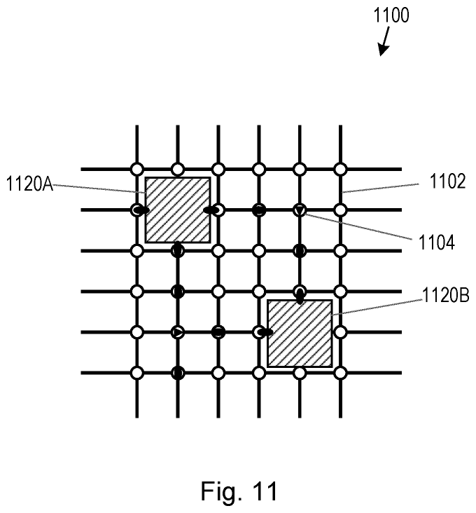

The optical coupler 206 may comprise one or more of: a mirror, an optical waveguide, and a lens. The optical coupler 206 may be adapted to optically couple the plurality of optical waveguides and the optical switch to the optical device by its position in the optical PCB and/or its function. For example, the optical coupler 206 may be adapted to optically couple the optical PCB 200 to the optical device by directing light out of a plane of the optical PCB 200 and/or towards the optical device. Thus, the optical coupler 206 may comprise a mirror that reflects light out of the plane of the optical PCB 200 towards the optical device (e.g., as shown in FIG. 9). Alternatively, the optical coupler 206 may comprise a waveguide that directs light towards the optical device (e.g., as shown in FIG. 10). The optical coupler 206 may further comprise a lens (e.g., a lithographic lens and/or a micro-lens) to increase the optical alignment tolerance of the optical coupling of the optical coupler 206 to the optical device (e.g., as shown in FIG. 9). The use of lenses to increase the optical alignment tolerance is described further with reference to FIG. 9.

In some embodiments, the optical PCB 200 may comprise a plurality of optical couplers 206 adapted to optically couple the plurality of optical waveguides 202 and the optical switch 204 to a plurality of optical devices. In this way, the optical PCB 200 may interconnect the plurality of optical devices, e.g., by an optical path provided by the optical waveguides 202.

The optical switch 204 is configured to direct light into one or more optical waveguides of the plurality of optical waveguides 202. The optical switch 204 is controllable to select the one or more optical waveguides into which light is directed. In other words, it is possible to change the optical path provided by the optical waveguides 202. Thus, a plurality of different optical paths may be configurable with the optical switch 204. As such, the optical PCB 200 can be configured differently for different applications, e.g., for interconnecting different numbers of optical devices and/or for coupling optical devices such as electro-optical devices to an electrical circuit such as an ASIC.

The optical switch 204 may be controllable to direct any percentage of the light reaching the optical switch 204 (i.e., from 0 to 100%) to the one or more selected optical waveguides.

The optical switch 204 may be controllable to direct light from one of the plurality of optical waveguides 202 into two or more of the plurality of optical waveguides 202 (e.g., the optical switch 204 may act as a splitter). The optical switch 204 may be controllable to combine light from two or more of the plurality of optical waveguides 202 (e.g., the optical switch 204 may act as a coupler).

The optical switch 204 may be controllable to select the one or more optical waveguides into which light is directed by being controllable to transmit light in a straight line, e.g., the selected optical waveguide may transmit light in the same direction as the optical waveguide through which light arrives at the optical switch 204.

The optical switch 204 may be controllable to select the one or more optical waveguides into which light is directed by being controllable to divert light within a plane of the optical PCB 200 by one or more angles, e.g., the selected optical waveguide(s) into which light is directed may transmit light in a different direction to the direction of the optical waveguide through which light arrives at the optical switch 204. Thus, the one or more angles may correspond to one or more angles (relative to the optical waveguide from which light arrives at the optical switch 204) at which there is an optical waveguide 202 optically coupled to the optical switch 204. The one or more angles may comprise one or more angles in a range from 45 degrees to 315 degrees. For example, the one or more angles may be one or more of: 45 degrees, 90 degrees, 180 degrees, 270 degrees, and 315 degrees.

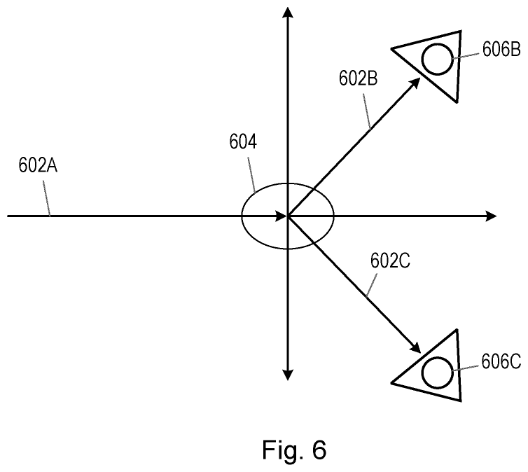

In some embodiments, the optical switch 204 may be controllable to select the one or more optical waveguides into which light is directed by being controllable to direct light to an optical waveguide 202 that is adapted to divert light out of a plane of the optical PCB 200. Such an optical switch configuration is described with reference to FIG. 6.

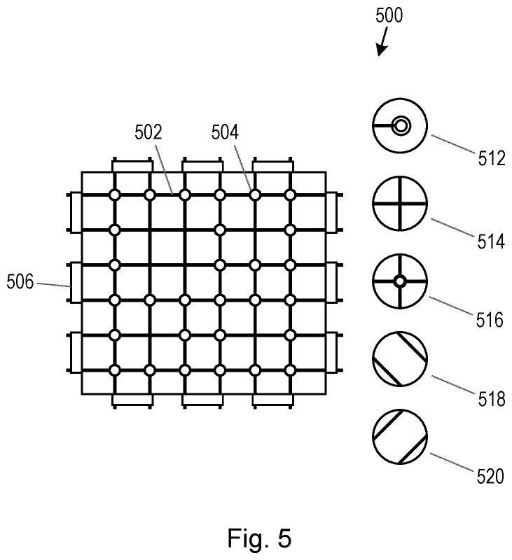

The optical PCB 200 may comprise a plurality of optical switches 204 located at intersections of the plurality of optical waveguides 202. For example, the plurality of optical waveguides 202 and the plurality of optical switches 204 may form a grid comprising horizontal rows and vertical columns within a plane of the optical PCB 200. An example of such a grid is described with reference to FIGS. 5, 7, 8A, 8B and 11. The grid may be referred to herein as a waveguide mesh or an optical waveguide mesh.

The optical switch 204 may be controllable by changing a refractive index of the optical switch 204. The optical switch 204 may comprise an interferometer, e.g., a Mach Zehnder interferometer. Interferometers are advantageous because they can be configured/reconfigured via an electrical command. Furthermore, interferometers provide optical switching with low power consumption, e.g., less than 5 mW. For example, interferometers may have a power consumption of around 1 mW.

The optical switch 204 may be electrically controllable (e.g., controlled electrically by an electrical component that is configured to actuate the optical switch 204). For example, an electrical signal for controlling the optical switch 204 may be a current or voltage that is applied to an electrical component to dissipate heat at or near to the optical switch 204. This may produce a thermo-optic effect that is capable of changing the output (i.e., function) of the optical switch 204.

The optical switch 204 may be adapted to be electrically coupled to an electrical PCB layer. For example, the optical switch 204 may be adapted to be electrically coupled to the electrical PCB layer by the optical switch 204 having a position on the optical PCB 200 that corresponds to a position of an electrical component on the electrical PCB layer, where the electrical component is configured to actuate the optical switch 204. The optical switch 204 may be adapted to be electrically coupled to the electrical PCB layer by an electrical contact (e.g., a metal pad) positioned on the optical PCB 200 (e.g., the electrical contact 912 shown in FIG. 9). For example, the electrical contact may be positioned on or near to the optical switch 204. Thus, the optical switch 204 of the optical PCB 200 may be controlled (e.g., configured/reconfigured) by the electrical PCB layer. For example, a controller may determine the function that each switch 204 is to perform and configure the switch or switches 204 accordingly.

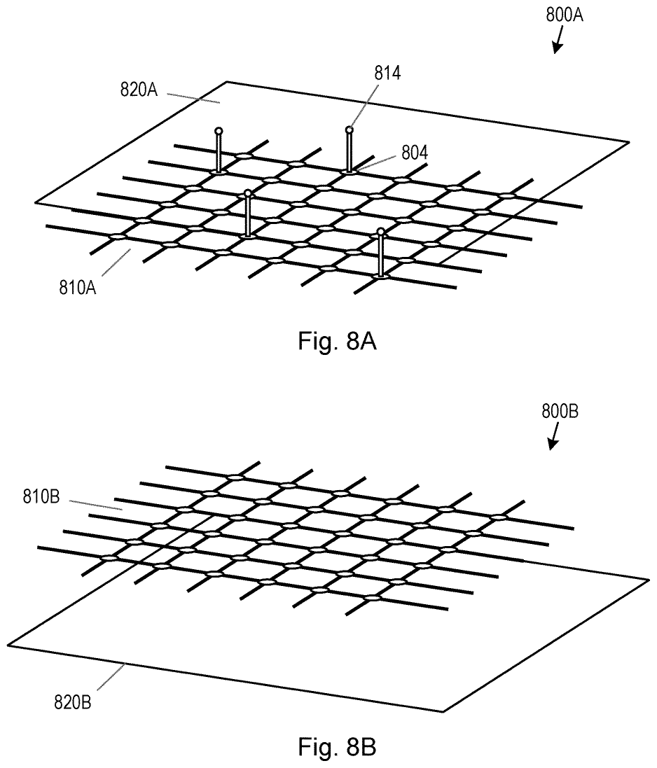

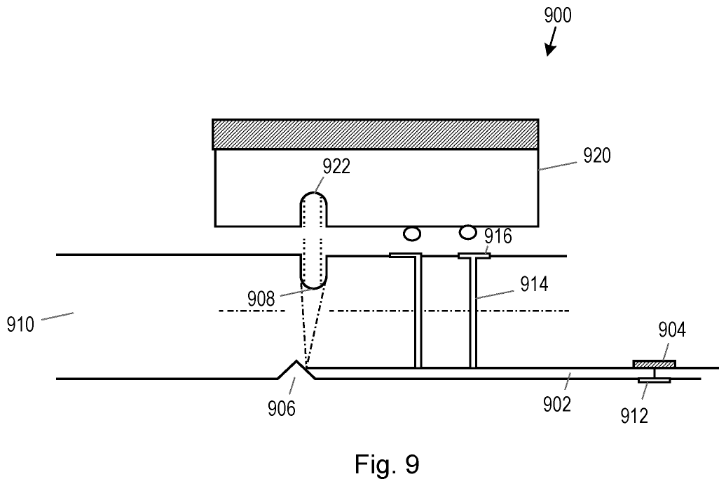

The optical PCB 200 may be configurable as an optical underlay (such that the electrical PCB layer is to be overlaid on the optical PCB 200, e.g., as shown in FIG. 8A). The optical PCB 200 may be configurable as an optical overlay (such that the optical PCB 200 is to be overlaid on the electrical PCB layer, e.g., as shown in FIG. 8B).

The optical PCB 200 may be adapted to electrically couple the optical device to the electrical PCB layer. For example, the optical PCB 200 may be configured such that the optical device may be positioned on the opposite side of the optical PCB 200 to the electrical PCB layer. The electrical coupling between the optical device and the electrical PCB layer may therefore be provided through the optical PCB 200. For example, the optical PCB 200 may comprise electrical vias that provide this electrical coupling. Electrical coupling provided by electrical vias is further described with reference to FIGS. 9 and 10. Thus, the electrical PCB layer may provide electrical power to the optical device and/or enable the optical device to exchange electrical signals with other devices.

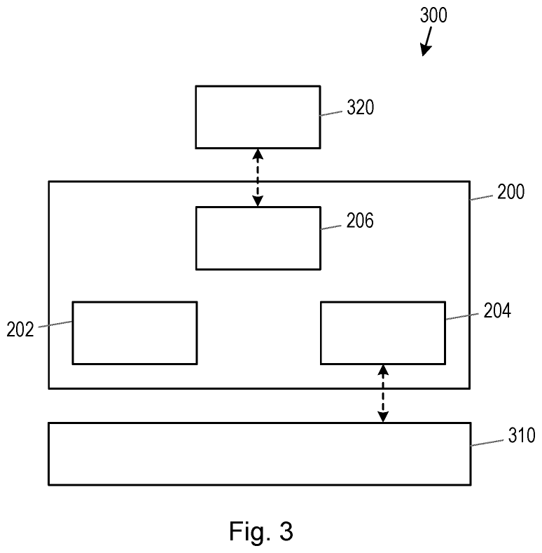

FIG. 3 is a block diagram illustrating a system 300 in accordance with some embodiments. The system 300 comprises the optical PCB 200 described with reference to FIG. 2. The system further comprises one or both of: an electrical PCB layer 310, and an optical device 320.

In some embodiments, the optical device 320 may be hosted on (e.g., mounted on) the optical PCB 200. In these embodiments, the electrical PCB layer 310 may be positioned on the opposite side of the optical PCB 200 to the optical device 320 (this configuration may be referred to herein as optical overlay).

In alternative embodiments, the electrical PCB layer 310 and the optical device 320 may both be positioned on the same side of the optical PCB 200 (this configuration may be referred to herein as optical underlay). In some of these embodiments, the optical device 320 may be hosted on (e.g., mounted on) the electrical PCB layer 310.

The optical PCB 200 and the electrical PCB layer 310 may, in combination, form a (single) PCB comprised of at least one optical layer and at least one electrical layer.

The electrical PCB layer 310 may be electrically coupled to the optical switch 204 of the optical PCB 200. For example, the electrical PCB layer 310 may comprise an electrical component configured to actuate the optical switch 204. The electrical component may have a position on the electrical PCB layer 310 that corresponds to a position of the optical switch 204 on the optical PCB 200. The electrical component may comprise, for example, any component that can change a refractive index of the optical switch 204. The electrical component may comprise, for example, one or more of: a resistor, a thermistor, and a voltage source. In this manner, the optical PCB 200 may be driven by the electrical PCB layer 310. For example, the electrical PCB layer 310 may control (e.g., configure/reconfigure) the optical switch 204.

The optical device 320 may be optically coupled to the optical coupler 206 of the optical PCB 200. In some embodiments, the optical device 320 may be positioned in a trench of the optical PCB 200 (e.g., 1018A and 1018B shown in FIG. 10).

The optical device 320 may be electrically coupled to the electrical PCB layer 310 via the optical PCB 200. For example, an electrical connection (e.g., an electrical via) may pass through the optical PCB 200 to electrically couple the optical device 320 on one side of the optical PCB 200 to the electrical PCB layer 310 on the opposite side of the optical PCB 200. An advantage of the optical underlay configuration compared to optical overlay configuration is that the optical device 320 can be electrically coupled to the electrical PCB layer 310 directly, i.e., without relying on electrical connections that pass through the optical PCB 200. In either configuration, the electrical PCB layer 310 may provide electrical power to the optical device 320 and/or enable the optical device 320 to exchange electrical signals with each other and with other devices.

The optical device 320 may comprise an optical coupler that is optically coupled to an optical coupler of the optical PCB 200. For example, the optical coupler of the optical device 320 may comprise a lens. A lens positioned in the optical device 320 between the optical coupler 206 of the optical PCB 200 and the optical device 320 may advantageously increase the optical alignment tolerance of the optical coupling between the optical PCB 200 to the optical device 320.

The optical device 320 may be an electro-optical device, such as a CPO device or an NPO device. The CPO device may comprise an optical module (e.g., a device for converting optical signals to electrical signals) coupled to an ASIC (i.e., the optical module and the ASIC are comprised in the same package). The NPO device may comprise an optical module (e.g., a device for converting optical signals to electrical signals) that is to be connected to an ASIC that is outside the NPO device. For example, the NPO device may be connected to an ASIC through the optical PCB 200 and/or through the electrical PCB layer 310. The optical device may be, for example, a transceiver, a further optical coupler, or a filter.

Thus, the optical PCB 200 provides a common optical PCB layer (e.g., a common optical PCB mask) that is configurable and reconfigurable for different applications, e.g., CPO/NPO applications. For example, the system 300 may be used to interconnect optical devices 320 such as CPO/NPO devices. The electrical PCB layer 310 may be varied (e.g., custom-made) to provide the electrical connections that are required realise any specific application. For example, an optical supplier may supply the (universal) optical PCB 200 to an electrical supplier. The electrical supplier may then design, align and deploy the electrical PCB layer 310. In other words, the optical PCB design is decoupled from the electrical PCB design. The non-recurring engineering (NRE) costs are therefore significantly reduced.

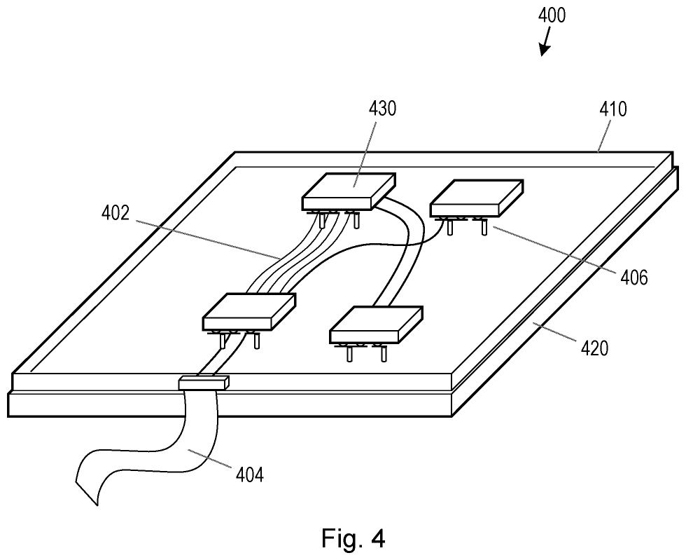

A specific example of the system 300 according to some embodiments is described with reference to FIG. 4.

FIG. 4 is a schematic illustrating a system 400 in accordance with some embodiments. The system 400 comprises an optical PCB 410 overlaid on an electrical PCB layer 420 (optical overlay). This may be achieved via layering. The optical PCB 410 and the electrical PCB layer 420 in combination form a single, combined PCB with optical and electrical layers. The optical PCB 410 may correspond to the optical PCB 200 of FIG. 2.

The optical PCB 410 interconnects a plurality of optical devices 430. For example, the optical devices 430 may comprise electro-optical devices such as CPO devices and/or NPO devices. In the system 400 of FIG. 4, the optical devices 430 are on the opposite side of the optical PCB 410 to the electrical PCB layer 420. However, those skilled in the art will appreciate that other configurations are possible (e.g., the optical devices 430 may be on the same side of the optical PCB 410 as the electrical PCB layer 420).

The optical PCB 410 comprises a plurality of optical waveguides and optical switches (referred to herein as a waveguide mesh), and the optical PCB 410 can be configured to interconnect the optical devices 430 in a desired manner by controlling the optical switches. In this way, different optical paths 402 between the optical devices 430 can be formed as required, e.g., to direct light between the optical devices 430. Such optical paths 402 are schematically shown in FIG. 4. Each optical path 402 may comprise one or more optical waveguides, where an optical waveguide refers to a waveguide segment, e.g., a waveguide segment between two optical switches or any other two components in the optical PCB 410. Some possible optical waveguide configurations will be described in more detail with reference to FIGS. 5-11.

The optical PCB 410 further comprises electrical vias 406 that pass vertically through the optical PCB 410 (from one side of the optical PCB 410 to the opposite side of the optical PCB 410) to electrically couple the optical devices 430 to the electrical PCB layer 420. This electrical coupling may be used, for example, to drive the optical devices 430 and/or to exchange electrical signals between the optical devices 430 and/or with other devices.

Furthermore, if the optical device 430 is an electro-optical device, the electrical vias may serve to connect the optical device 430 to the electrical PCB layer 420 so that the optical device 430 can be connected to an ASIC.

The system 400 further comprises a port for connecting an optical fibre 404 (e.g., ribbon) to the system 400. The port may be located at a side of the optical PCB 410. The optical switches in the optical PCB 410 may be further configured to direct light (e.g., signals) towards the fibre 404 attached at the side port.

Thus, the optical PCB 410 provides a universal base layer for all custom electrical PCB designs that comprise one or more optical devices.

FIG. 5 is a schematic illustrating an optical PCB 500 according to some embodiments. The optical PCB 500 may be a specific implementation of the optical PCB 200 of FIG. 2.

The optical PCB 500 comprises a plurality of optical waveguides 502 and a plurality of optical switches 504, referred to as an optical waveguide mesh. Here, an optical waveguide 502 refers to a segment of waveguide between two optical switches 504. Thus, optical switches 504 are located at intersections of the optical waveguides 502. The plurality of optical waveguides 502 and the plurality of optical switches 504 form a grid comprising horizontal rows and vertical columns within a plane of the optical PCB 500. Thus, the optical switches 504 are placed at regular distances within the optical PCB 500 and are coupled horizontally and vertically.

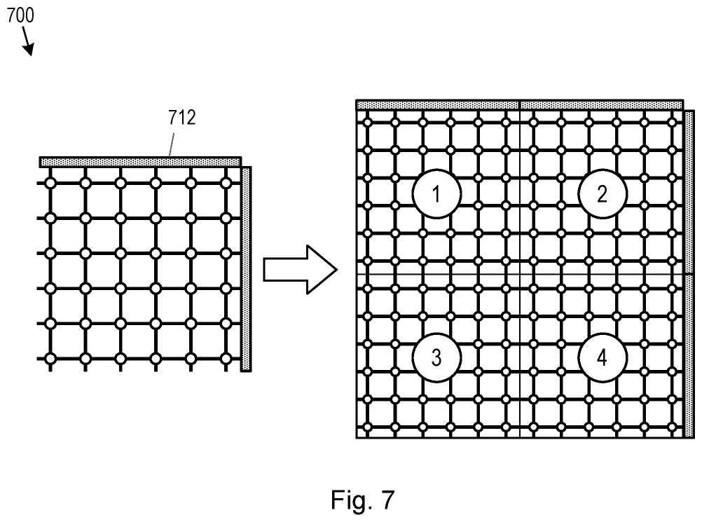

The optical PCB 500 further comprises side ports 506. The side ports 506 may be configured for connecting optical fibres (e.g., ribbons or fibre foils) to the optical PCB 500 and/or for connecting transceivers to the optical PCB 500, e.g., for interconnection with other boards, devices or remote nodes, such as those that cannot be integrated onto the optical PCB 500, e.g., due to higher power requirements. The side ports 506 may enable interconnection of multiple optical PCBs 500, as described with reference to FIG. 7.

The optical switches 504 of FIG. 5 may be, for example, interferometers. Any optical switch 504 may be configured to route a percentage of the light reaching the optical switch 504 from 0 to 100% to any of the optical waveguides interconnected by the optical switch 504. The optical switches 504 may be controlled (e.g., driven/actuated) by electrical components in an electrical layer, e.g., a thermistor or resistor. Such electrical layers 310, 420 were described with reference to FIGS. 3 and 4 respectively (an electrical layer is not shown in FIG. 5). The electrical component may be positioned in correspondence to (e.g., directly above/on/below) the optical switch 504 that it is to control.

The symbols 512, 514, 516, 518 and 520 depicted in FIG. 5 represent different functions of an optical switch 504. Each function indicates how the optical switch 504 may be configured to direct light. In other words, the function indicates the one or more optical waveguides 502 into which light may be directed by the optical switch 504. Any given optical switch 504 may be controllable to perform any one or more of these functions. For example, a controller may determine the function that each switch 504 is to perform and configure the switches 504 accordingly. By cascading multiple optical switches, it is possible to increase the number of path selection options.

An optical switch 504 may connect (e.g., couple) the optical waveguide mesh to an ASIC, as represented by symbol 512. Thus, the optical switch 504 may direct (e.g., transmit) light towards the ASIC.

An optical switch 504 may provide no coupling, such that the light passes straight through the optical switch 504, as represented by symbol 514. Thus, the optical switch 504 may transmit light in a straight line. This optical switch function may be referred to as a pass-through.

An optical switch 504 may split and/or couple light, as represented by symbol 516. For example, light from one waveguide 502 may be split by the optical switch 504 and directed into two waveguides 502. The amount of light directed into each waveguide may also be controllable by controlling the optical switch 504. Furthermore, light from two or more waveguides 502 may be combined. For example, light from two waveguides 502 may be combined and directed into one waveguide 502. This optical switch function may be referred to as power split/coupling.

An optical switch 504 may direct light out of the plane of the optical PCB 500, as represented by symbols 518 and 520. For example, the optical switch 504 may be configured to direct light into an optical waveguide 502 that is adapted to direct light out of a plane of the optical PCB 500 (in FIG. 5, this could be into or out of the plane of the page). For example, the light may be diverted by 90 degrees clockwise in a plane perpendicular to the plane of the optical PCB 500 (i.e., the light is diverted into the page of FIG. 5), and this function is represented by symbol 518. The light may be diverted 270 degrees clockwise in a plane perpendicular to the plane of the optical PCB 500 (i.e., the light is diverted out of the page of FIG. 5), and this function is represented by symbol 520. The optical waveguide 502 may be adapted to divert light out of the plane of the optical PCB 500 by, for example, directing the light towards a mirror (e.g., the waveguide 502 may be coupled with a mirror).

These functions 518, 520 may be used to direct light to an optical device, e.g., the optical device 320 of FIG. 3. For example, the mirror may direct the light to an optical port of a CPO or NPO device placed above the optical PCB 500.

An example of an optical switch configured to perform these functions 518, 520 is described with reference to FIG. 6.

FIG. 6 illustrates a possible function of an optical switch 604 according to some embodiments. The optical switch 604 may be comprised in an optical PCB, as described with reference to FIGS. 2-5.

Light reaches the optical switch 604 from a first optical waveguide 602A. If the optical switch 604 is configured according to symbol 520, the optical switch 604 directs light into a second optical waveguide 602B. To do so, the optical switch 604 may divert the light within the plane of the optical PCB by a specific angle. For example, the direction of light in the second optical waveguide 602B may be at an angle of 315 degrees (in a clockwise direction) relative to the direction of light in the first optical waveguide 602A (though the skilled person will appreciate that other angles could be used). Thus, the light is diverted by 315 degrees in a clockwise direction (or equivalently 45 degrees in the anti-clockwise direction) within the plane of the optical PCB. The second optical waveguide 602B directs light to a mirror 606B, which reflects the light out of the plane of the optical PCB.

If the optical switch 604 is configured according to symbol 518, the optical switch 604 directs light into a third optical waveguide 602C. To do so, the optical switch 604 may divert the light within the plane of the optical PCB by a specific angle. For example, the direction of light in the third optical waveguide 602C may be at an angle of 45 degrees (in a clockwise direction) relative to the direction of light in the first optical waveguide 602A. Thus, the light is diverted by 45 degrees in a clockwise direction within the plane of the optical PCB. The third optical waveguide 602C directs light to a mirror 606C, which reflects the light out of the plane of the optical PCB.

In some embodiments, the optical switch 604 may be configured to split the light and perform both functions 518 and 520.

The purpose of directing light out of the plane of the optical PCB may be to optically couple the waveguide mesh of the optical PCB to an optical device, e.g., as described with reference to FIGS. 9 and 10. Thus, the mirror 606B, 606C may act as an optical coupler (e.g., the optical coupler 206 of FIG. 2).

FIG. 7 illustrates the interconnection of optical PCBs in accordance with some embodiments.

FIG. 7 shows an optical PCB 700, which could correspond to any of the optical PCBs described with reference to FIGS. 2-5. The optical PCB 700 comprises side ports 712 for interconnecting a plurality of optical PCBs. For example, the side ports 712 may comprise multi-fibre push on (MPO) connectors, or any other type of connector.

FIG. 7 illustrates the interconnection of four optical PCBs labelled 1, 2, 3 and 4. The four optical PCBs may be the same or different to each other.

The ports/connector areas may be provisioned in advance by the optical supplier. The optical supplier may attach multiple optical PCBs together based on the desired application. An advantage of the combination of the optical PCBs being managed by the optical supplier is that the number of interconnection points can be reduced and therefore the need for high precision production is reduced. This in turn reduces the NRE costs for customer-specific applications.

Alternatively, the optical supplier may provide the optical PCBs as modular components (with the required ports/connector areas) to an electrical supplier. The electrical supplier may then handle the attaching of multiple optical PCBs according to customer-specific applications, as well deploying the electrical PCB layer (e.g., the electrical PCB layer 310 described with reference to FIG. 3). In this case, the optical PCBs supplied to the electrical supplier are universal (i.e., not customer-specific) which greatly simplifies the production and reduces the precision requirements compared to existing techniques. As such, the NRE costs are almost null.

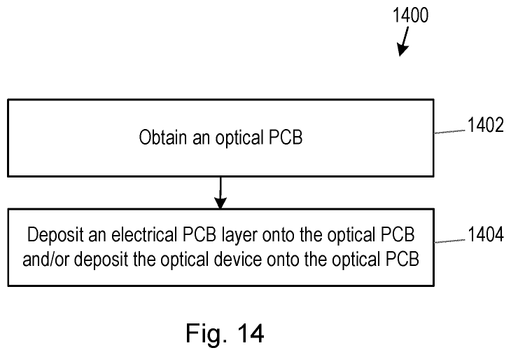

Fabrication methods according to certain embodiments are described in more detail with reference to FIGS. 12 to 17C.

FIG. 8A illustrates a system 800A in accordance with some embodiments. The system 800A comprises an optical PCB 810A, which may be a specific implementation of the optical PCB 200 described with reference to FIG. 2. The system 800A further comprises an electrical PCB layer 820A, which may be a specific implementation of the electrical PCB layer 310 described with reference to FIG. 3. The electrical PCB layer 820A is overlaid on the optical PCB 810A. Thus, the optical PCB 810A comprises an optical PCB underlay.

Although not shown in FIG. 8A, the system 800A may further host one or more optical devices (e.g., the optical devices 320 described with reference to FIG. 3). The optical devices may be hosted on the electrical PCB layer 820A. Thus, in these embodiments the optical devices are on the same side of the optical PCB 810A as the electrical PCB layer 820A.

The system 800A comprises optical switches 804 which are electrically controllable. For example, the optical switches 804 may comprise a metal pad positioned on the optical switch 804 for providing or improving the electrical control. The electrical PCB layer 820A comprises electrical components 814, where each electrical component 814 is positioned close enough to a corresponding optical switch 804 to electrically control the optical switch 804 (the electrical control is schematically represented in FIG. 8A by vertical lines between the optical switch 804 and the electrical component 814). These optical switches 804 with corresponding electrical components 814 in the electrical PCB layer 820A provide points of flexibility that enable the optical PCB 810A to be configured/reconfigured for specific applications.

FIG. 8B illustrates a system 800B in accordance with alternative embodiments to those illustrated by FIG. 8A.

The system 800B comprises an optical PCB 810B, which may be a specific implementation of the optical PCB 200 described with reference to FIG. 2. The system 800B further comprises an electrical PCB layer 820B, which may be a specific implementation of the electrical PCB layer 310 described with reference to FIG. 3. In contrast to the system 800A of FIG. 8A, the electrical PCB layer 820B in the system 800B of FIG. 8B is positioned underneath the optical PCB 810B. Thus, the optical PCB 810B comprises an optical PCB overlay.

Although not shown in FIG. 8B, the system 800B may further host one or more optical devices (e.g., the optical device 320 described with reference to FIG. 3). The optical devices may be hosted on the optical PCB 810B. In these embodiments, the optical devices may be on the opposite side of the optical PCB 810B to the electrical PCB layer 820B. The optical devices may be electrically coupled to the electrical PCB layer 820B using electrical connections (e.g., electrical vias) that pass through the optical PCB 810B. These electrical connections may provide fixed points on the optical PCB 810B that may be connected to the electrical PCB layer 820B. Such electrical connections will be described with reference to FIGS. 9 and 10.

Although not shown in FIG. 8B, the optical switches comprised in the optical PCB 810B are electrically controllable in the manner described with reference to FIG. 8A. The electrical PCB layer 820B may comprise electrical components (not shown) that are positioned to electrically control the optical switches. By configuring the optical switches, the optical PCB 810B can be configured/reconfigured for different applications.

Notably, the same optical PCB may be used for both the configuration of FIG. 8A and the configuration of FIG. 8B. This is one of the advantages of the optical PCB being configurable/reconfigurable. As such, the production of the optical PCB is simplified, and the production costs are reduced.

FIG. 9 illustrates a system 900 in accordance with some embodiments.

FIG. 9 shows a system 900 comprising an optical PCB 910 and an optical device 920. For example, the optical PCB 910 may be a specific implementation of the optical PCB 200 described with reference to FIG. 2. The optical device 920 may be a specific implementation of the optical device 320 described with reference to FIG. 3.

The optical device 920 is mounted on the optical PCB 910. Thus, the optical PCB 910 is configured as an optical PCB overlay (e.g., as shown in FIG. 8B).

The optical PCB 910 comprises an optical switch 904 and an optical waveguide 902 which optically couples the optical switch 904 to a mirror 906 (e.g., a lithographic mirror and/or a micro-mirror). The mirror 906 is configured to reflect light from the optical waveguide 902 out of the plane of the optical PCB 910 towards the optical device 920. Thus, the mirror 906 acts as an optical coupler to optically couple the waveguide 902 and the switch 904 (i.e., the waveguide mesh of the optical PCB 910) to the optical device 920. This configuration is suitable for optical devices 920 that have a vertical optical coupling, such as those that have an optical port on the bottom of the device 920, e.g., those that use grating couplers as the optical port.

The optical PCB 910 further comprises a lens 908 (e.g., a lithographic lens and/or a micro-lens). The lens 908 is positioned between the mirror 906 and the optical device 920. The lens 908 is aligned with the mirror 906. The lens 908 increases the optical alignment tolerance of the optical coupling between the optical PCB 910 (e.g., the mirror 906 comprised in the optical PCB 910) and the optical device 920. For example, the lens may increase the optical alignment tolerances from sub microns to more than 10 microns. The use of lenses to increase optical alignment tolerance is described in more detail in WO2021/180303. The lens 908 may be referred to as an optical coupler. The lens 908 and the mirror 906 may together be referred to as an optical coupler.

The optical device 920 also comprises a lens 922 (e.g., at an optical port of the optical device 920). The lens 922 is aligned with an optical port of the optical device 920. The lens 922 is located in a corresponding position to the mirror 906 and/or lens 908. In other words, the lens 922 is located to receive light that is reflected from the mirror 906 and/or transmitted through the lens 908. The lens 922 further increases the optical alignment tolerance.

The optical PCB 910 further comprises one or more electrical contacts 916 and one or more electrical vias 914 for electrically coupling the optical device 920 to electrical wiring of the system 900. For example, the electrical contacts 916 may be provided with ‘standard’ pitch to allow the soldering of a ball grid array of the optical device 920 (e.g., the pitch may correspond to the pitch of metal balls of certain standard optical devices such as standard CPO devices). Electrical vias 914 may be provided to connect the electrical contacts 916 of the optical PCB 910 to the electrical wiring. The electrical wiring may comprise an electrical layer within the optical PCB 910 and/or an electrical PCB layer, e.g., the electrical PCB layer 310 described with reference to FIG. 3 or the electrical PCB layer 820B described with reference to FIG. 8B (not shown in FIG. 9). The electrical PCB layer may therefore comprise corresponding electrical contacts for connecting to the electrical vias 914.

The optical PCB 910 further comprises an electrical contact 912 for realising or improving the electrical control of the optical switch 904. For example, the electrical contact 912 may comprise an interferometer pad, e.g., a metal pad. The electrical contact 912 may be positioned on or near to the optical switch 904.

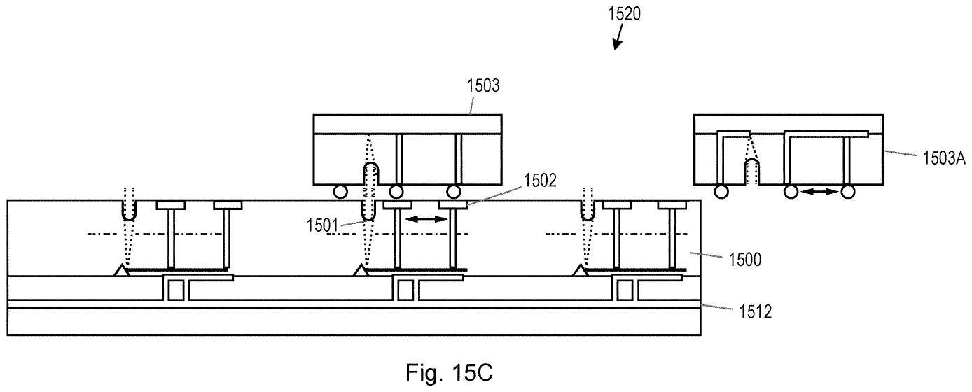

The system 900 may be fabricated using the method of any of FIGS. 14, 15 and 16A-C.

FIG. 10 illustrates a system 1000 in accordance with some embodiments.

FIG. 10 shows a system 1000 comprising an optical PCB 1010 and two optical devices 1020A and 1020B. For example, the optical PCB 1010 may be a specific implementation of the optical PCB 200 described with reference to FIG. 2. The optical devices 1020A, 1020B may be specific implementations of the optical device 320 described with reference to FIG. 3.

The optical device 1020 is mounted on the optical PCB 1010. Thus, the optical PCB 1010 may be configured as an optical PCB overlay (e.g., as shown in FIG. 8B).

The optical PCB 1010 is distinguished from that shown in FIG. 9 in that the optical PCB 1010 comprises trenches 1018A, 1018B and the optical devices 1020A, 1020B are each housed in a trench 1018A, 1018B. The trenches 1018A, 1018B may be fabricated via lithography. The trenches 1018A, 1018B may be larger enough to accommodate different optical devices 1020A, 1020B of different sizes. This configuration is suitable for optical devices 1020A, 1020B that have a horizontal optical coupling, such as those that that have an optical port at the edge of the device, as shown in FIG. 10.

The optical PCB 1010 comprises an optical switch 1004 and an optical waveguide 1002 which optically couples the optical switch 1004 to a mirror 1006A. The mirror 1006A is configured to reflect light from the optical waveguide 1002 out of the plane of the optical PCB 1010 towards the optical device 1020A (e.g., ‘towards’ here means that the optical mirror directs the light along a path that takes the light closer to the optical device 1020A). The light is incident on a second mirror 1006B that reflects the light into an optical waveguide 1008 which directs the light towards a port of the optical device 1020A. Thus, the optical waveguide 1008 is aligned to an optical port of the optical device 1020A.

The mirror 1006A, the mirror 1006B, and the waveguide 1008 each act as an optical coupler to optically couple the waveguide mesh of the optical PCB 1010 to the optical device 1020A. The optical PCB 1010 further comprises one or more electrical contacts 1016 and one or more electrical vias 1014 to electrically couple the optical device 1020A to electrical wiring.

The electrical wiring may comprise an electrical layer within the optical PCB 1010 and/or an electrical PCB layer, e.g., the electrical PCB layer 310 described with reference to FIG. 3 or the electrical PCB layer 820B described with reference to FIG. 8B (not shown in FIG. 10). The electrical contacts 1016 are located at the bottom of the trench 1018A, 1018B. The electrical vias 1014 pass from the bottom of the trench 1018A, 1018B through the optical PCB 1010.

The optical PCB 1010 further comprises an electrical contact 1012 for realising the electric control of the optical switch 1004. For example, the electrical contact 1012 may comprise an interferometer pad, e.g., a metal pad.

The system 1000 may be fabricated using the method of any of FIGS. 14, 15 and 17A-C.

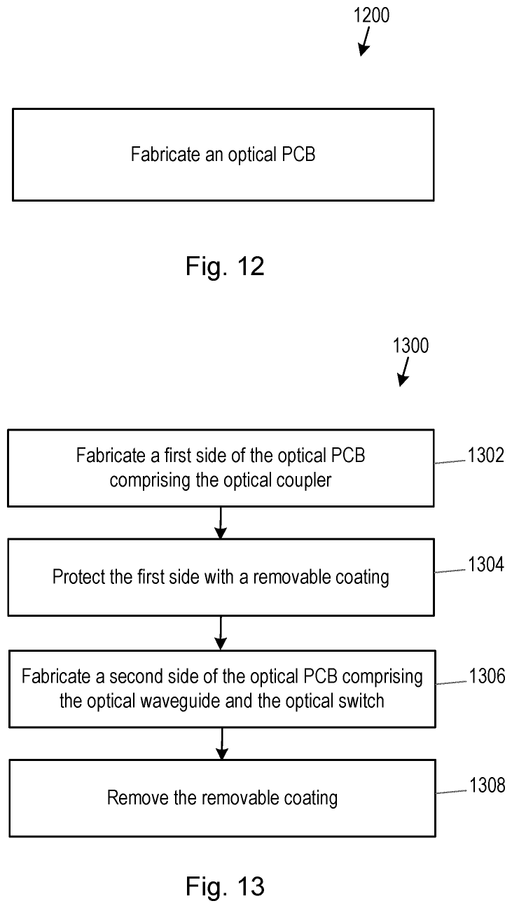

FIG. 11 illustrates a system 1100 in accordance with some embodiments.

The system 1100 comprises an optical PCB comprising a plurality of optical waveguides 1102 and a plurality of optical switches 1104 (i.e., a waveguide mesh). The system 1100 further comprises two optical devices 1120A, 1120B mounted on the optical PCB. For example, they may be mounted in trenches as shown in FIG. 10.

The shaded optical switches 1104 illustrate how the optical PCB may be configured to interconnect the two optical devices 1120A, 1120B. The shaded optical switches 1104 show optical switches that have each been electrically controlled (e.g., using a controller) to select the one or more optical waveguides into which light is to be directed by the optical switch 1104, with the result that the optical PCB optically couples the two optical devices 1120A, 1120B. The optical devices 1120A, 1120B have been placed on the optical PCB and aligned to one or more optical ports in the waveguide mesh of the optical PCB.

FIG. 12 illustrates a method 1200 of fabricating an optical PCB in accordance with some embodiments. The optical PCB may, for example, be the optical PCB described with reference to any of FIGS. 2-11.

In particular, the optical PCB comprises a plurality of optical waveguides; an optical switch; and an optical coupler adapted to optically couple the plurality of optical waveguides and the optical switch to an optical device. The optical switch is configured to direct light into one or more optical waveguides of the plurality of optical waveguides. Furthermore, the optical switch is controllable to select the one or more optical waveguides into which light is directed. The method 1200 may comprise a step of fabricating a first side of the optical PCB comprising the optical coupler. The method 1200 may further comprise a step of fabricating a second side of the optical PCB comprising the optical waveguide and the optical switch.

The first side may be opposite to the second side. The first side may be fabricated before the second side.

The method 1200 may further comprise, after fabricating the first side, protecting the first side with a removable coating before fabricating the second side. The method 1200 may further comprise, after fabricating the second side, removing the removable coating.

Fabricating the first side may comprise fabricating a trench in the first side of the optical PCB for housing the optical device.

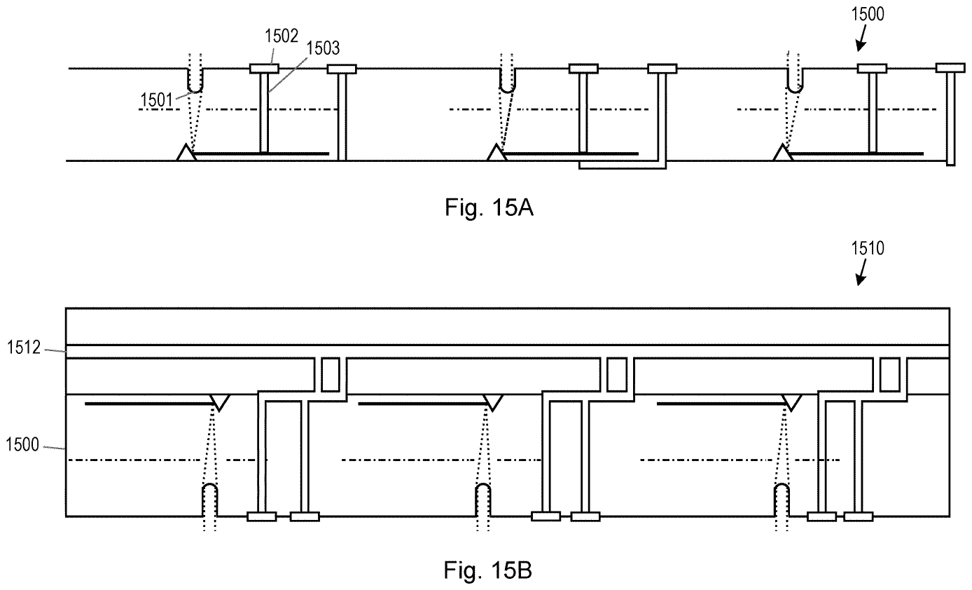

FIG. 13 illustrates a method 1300 of fabricating an optical PCB in accordance with some embodiments. The method 1300 is a specific embodiment of the method 1200. The optical PCB may, for example, be the optical PCB described with reference to any of FIG. 2.

At step 1302, a first side of the optical PCB comprising the optical coupler is fabricated, e.g., using lithography. The optical PCB may be comprised of glass or a polymer.

At step 1304, the first side is protected with a removable coating.

At step 1306, a second side of the optical PCB comprising the optical waveguide and the optical switch is fabricated, e.g., using lithography.

At step 1308, the removable coating is removed.

FIG. 14 illustrates a method of fabricating a system in accordance with some embodiments. The system may, for example, be the system described with reference to FIG. 3.

The method comprises, at step 1402, obtaining an optical PCB fabricated according to the method of FIG. 12 or 13. The optical PCB may be the optical PCB 200 of FIG. 2 or 3.

The method further comprises, at step 1404, one or both of depositing an electrical PCB layer onto the optical PCB; and depositing the optical device onto the optical PCB.

The electrical PCB layer may be the electrical PCB layer 310 described with reference to FIG. 3. The optical device may be the optical device 320 described with reference to FIG. 3.

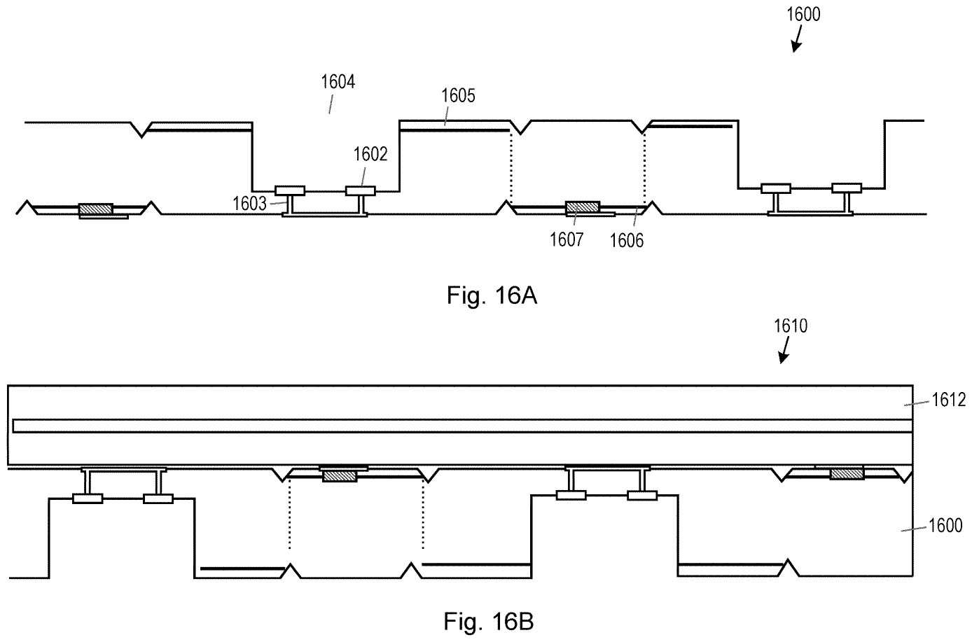

FIGS. 15A, 15B and 15C illustrate a method of fabricating an optical PCB 1500 and a system 1520 in accordance with some embodiments. The method may correspond to the method of FIG. 12, 13 or 14. The optical PCB 1500 (and the corresponding system 1520) is suitable for coupling optical devices that use vertical coupling, e.g., as described with reference to FIG. 9.

The optical PCB 1500 is fabricated first and constitutes the basis of the PCB 1510. The optical PCB 1500 provides a layer that is common to multiple PCB design options due to its reconfigurability.

It is convenient to firstly fabricate the side of the optical PCB 1500 that comprises the one or more optical couplers 1501, e.g., lenses. This first side may further comprise one or more electrical contacts 1502 (e.g., metal pads) for the electrical connection with one or more optical devices 1503.

The first side of the optical PCB 1500 may then be protected with a removable coating and the optical PCB 1500 can be turned to fabricate the optical waveguide mesh on the other side.

Electric vias 1503 may then be realised in a further lithographic step or via drilling. It is important to avoid intercepting the optical waveguides in this step.

Electrical contacts (e.g., metal pads/lines) for electrical control of optical switches comprised in the optical PCB 1500 may be deposited onto the surface of the optical PCB 1500 after the lithography has been completed (electrical contacts and optical switches are not shown in FIGS. 15A-C but may, for example, correspond to the optical switch 904 and electrical contact 912 shown in FIG. 9).

The resulting optical PCB 1500 obtained by these steps is shown in FIG. 15A.

The electrical PCB layer(s) 1512 are then laminated on top of the optical PCB 1500. The electrical PCB layer(s) 1512 are designed to exploit the multiple options provided by the configurable/reconfigurable optical PCB 1500.

The resulting PCB 1510 obtained by this step is shown in FIG. 15B.

Finally, the PCB 1510 is turned upside down and the optical devices 1503 (e.g., CPO/NPO devices) may be assembled on the side of the optical PCB 1500 that contains the optical couplers 1501 (e.g., alignment lenses) and optionally the electrical contacts 1502 (e.g., metal pads).

The removable coating (on the first side of the optical PCB) may be removed just before the optical devices 1503 are assembled onto the first side of the optical PCB 1500, which may advantageously provide an optimal surface on the first side of the optical PCB 1500 for optical coupling. This fabrication method may be referred to as surface mount since the optical devices 1503 are mounted on the surface of the optical PCB 1500.

The resulting system 1520 obtained by this step is shown in FIG. 15C.

FIG. 15C also shows a more detailed view of an optical device 1503A, and in particular shows electrical vias inside the optical device 1503A.

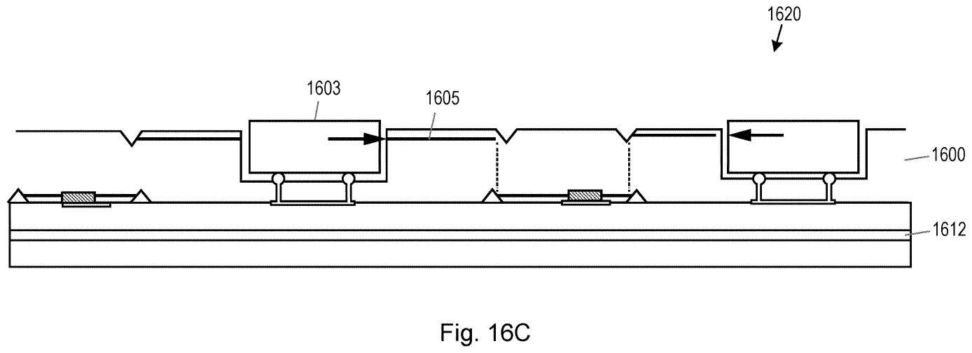

FIGS. 16A, 16B and 16C illustrate a method of fabricating an optical PCB 1600 and a system 1620 in accordance with some embodiments. The method may be a specific implementation of the method of FIG. 12, 13 or 14. The optical PCB 1600 (and the corresponding system 1620) is suitable for coupling to optical devices 1603 using horizontal coupling, e.g., as described with reference to FIG. 10.

In these embodiments, the optical PCB 1600 has multiple trenches 1604 in which optical devices 1603 are to be positioned. Thus, there is at least one optical waveguide 1605 in the optical PCB 1600 that is aligned to the optical port of each of the optical devices 1603 (e.g., to act as an optical coupler).

The trenches 1604 may be fabricated via lithography and metal pads 1602 may be deposited on the bottom of the trench 1604. The trench size may be made large enough to accommodate different optical device sizes.

In a first implementation, the electrical vias 1603 may be fabricated (e.g., using lithography) during the realization of the side of the optical PCB 1600 with the trenches 1604.

In a second implementation, the electrical vias 1603 may be fabricated (e.g., using lithography) during the realization of the side of the optical PCB 1600 that contains the optical waveguides 1606 and the optical switch 1607 (i.e., the waveguide mesh). This second implementation is suitable for optical devices 1603 that have the optical port at the edge of the chip (e.g., as described with reference to FIG. 10).

Electrical contacts (e.g., metal lines) for electrical control of the optical switches 1607 may be deposited onto the surface of the optical PCB 1600 after the lithography has been completed.

The resulting optical PCB 1600 obtained by these steps is shown in FIG. 16A.

The electrical PCB layer(s) 1612 may then be laminated on top of the optical PCB 1600, on the side of the optical PCB 1600 containing the waveguide mesh (i.e., the plurality of waveguides 1606 and switches 1607, which may form a grid comprising horizontal rows and vertical columns).

The resulting PCB 1610 obtained by this step is shown in FIG. 16B.

The PCB 1610 may then be turned upside down and the optical devices 1603 may be mounted onto the optical PCB 1600. This fabrication method may be referred to as flip chip assembly.

The resulting system 1620 obtained by this step is shown in FIG. 16C.

The method of FIGS. 15A-C is advantageously simpler than the method of FIGS. 16A-C because there is no requirement for vertical alignment of optical devices 1603 in a trench 1604, and no requirement to deposit an electrical contact (e.g., metal pad) on the bottom of the trench 1604.

Thus, according to the present disclosure, there is provided an optical PCB and a system comprising an optical PCB, as well as a method of fabricating an optical PCB and a method of fabricating a system comprising an optical PCB. The described fabrication methods enable the fabrication of an optical PCB that can be configured/reconfigured for use with any custom electrical PCB design for different applications. Thus, an optical PCB does not need to be re-designed and manufactured for each different application.

It should be noted that the above-mentioned embodiments illustrate rather than limit the idea, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. An optical printed circuit board (PCB) comprising:
a plurality of optical waveguides;
an optical switch; and
an optical coupler adapted to optically couple the plurality of optical waveguides and the optical switch to an optical device;
wherein the optical switch is configured to direct light into one or more optical waveguides of the plurality of optical waveguides, and wherein the optical switch is controllable to select the one or more optical waveguides into which light is directed.

2. The optical PCB of claim 1, wherein the optical switch is controllable to direct light from one of the plurality of optical waveguides into two or more of the plurality of optical waveguides.

3. The optical PCB of claim 1, wherein the optical switch is controllable to combine light from two or more of the plurality of optical waveguides.

4. The optical PCB of claim 1, wherein the optical switch is controllable to select the one or more optical waveguides into which light is directed by being controllable to transmit light in a straight line.

5. The optical PCB of claim 1, wherein the optical switch is controllable to select the one or more optical waveguides into which light is directed by being controllable to divert light within a plane of the optical PCB by one or more angles.

6. The optical PCB of claim 5, wherein the one or more angles comprise one or more angles in a range from 45 degrees to 315 degrees.

7. The optical PCB of claim 5, wherein the one or more angles comprise one or more of: 45 degrees, 90 degrees, 180 degrees, 270 degrees, and 315 degrees.

8. The optical PCB of claim 1, wherein the optical switch is controllable to select the one or more optical waveguides into which light is directed by being controllable to direct light to an optical waveguide that is adapted to divert light out of a plane of the optical PCB.

9. The optical PCB of claim 1, wherein the optical PCB comprises a plurality of optical switches located at intersections of the plurality of optical waveguides.

10. The optical PCB of claim 9, wherein the plurality of optical waveguides and the plurality of optical switches form a grid comprising horizontal rows and vertical columns within a plane of the optical PCB.

11-17. (canceled)

18. The optical PCB of claim 1, wherein the optical PCB further comprises a trench for housing the optical device, and wherein the optical coupler is adapted to optically couple the optical PCB to the optical device by directing light towards the trench.

19. (canceled)

20. A system comprising:
the optical PCB of claim 1:
an electrical PCB layer electrically coupled to the optical switch of the optical PCB; and
the optical device optically coupled to the optical coupler of the optical PCB.

21. The system of claim 20, wherein the electrical PCB layer comprises the electrical component configured to actuate the optical switch, wherein the electrical component has the position on the electrical PCB layer that corresponds to the position of the optical switch on the optical PCB.

22-26. (canceled)

27. A method of fabricating an optical printed circuited board, PCB, the optical PCB comprising:
a plurality of optical waveguides;
an optical switch; and
an optical coupler adapted to optically couple the plurality of optical waveguides and the optical switch to an optical device;
wherein the optical switch is configured to direct light into one or more optical waveguides of the plurality of optical waveguides, and wherein the optical switch is controllable to select the one or more optical waveguides into which light is directed.

28. The method of claim 27, wherein the method comprises:
fabricating a first side of the optical PCB comprising the optical coupler; and
fabricating a second side of the optical PCB comprising the optical waveguide and the optical switch.

29. The method of claim 28, wherein the first side is opposite to the second side.

30. The method of claim 28, wherein the first side is fabricated before the second side.

31. The method of claim 30, wherein the method further comprises:
after fabricating the first side, protecting the first side with a removable coating before fabricating the second side.

32. (canceled)

33. The method of claim 28, wherein fabricating the first side comprises fabricating a trench in the first side of the optical PCB for housing the optical device.

34. A method of fabricating a system, wherein the method comprises:
obtaining an optical PCB fabricated according to the method of claim 27:
depositing an electrical PCB layer onto the optical PCB; and
depositing the optical device onto the optical PCB.
